(19) United States
(12) Patent Application Publication
(10) Pub. No.: US 2024/0292596 A1
(43) Pub. Date: Aug. 29, 2024

(54) SEMICONDUCTOR DEVICE INCLUDING CAPACITOR AND METHOD OF FABRICATING THE SAME

(71) Applicant: Samsung Electronics Co., Ltd., Suwon-si (KR)

(72) Inventors: Intak Jeon, Suwon-si (KR); Jungmin Park, Suwon-si (KR); Hanjin Lim, Suwon-si (KR); Hyungsuk Jung, Suwon-si (KR)

(21) Appl. No.: 18/489,189

(22) Filed: Oct. 18, 2023

(30) Foreign Application Priority Data
Feb. 24, 2023 (KR) 10-2023-0025130

(51) Int. Cl. H10B 12/00

(52) U.S. Cl. CPC H10B 12/315; H10B 12/033

(57) ABSTRACT

A semiconductor device includes a lower structure, a capacitor on the lower structure, the capacitor including a first bottom electrode, which is extended in a direction perpendicular to a bottom surface of the lower structure, and a second bottom electrode, which is provided on the first bottom electrode, a bottom supporting pattern supporting the first bottom electrode, and a top supporting pattern provided on the bottom supporting pattern to support the first bottom electrode. The first bottom electrode includes a first material, and the second bottom electrode may include a second material. A work function of the second material is greater than a work function of the first material.

### CROSS-REFERENCE TO RELATED APPLICATIONS

This U.S. non-provisional patent application claims priority under 35 U.S.C. § 119 to Korean Patent Application No. 10-2023-0025130, filed on Feb. 24, 2023, in the Korean Intellectual Property Office, the entire contents of which are hereby incorporated by reference.

### BACKGROUND

The present disclosure relates to a semiconductor device including a capacitor and a method of fabricating the same.

Recently, as the integration density of semiconductor devices (e.g., dynamic random access memory (DRAM) devices) has increased, the area of a unit memory cell has decreased, but it is necessary to maintain or increase a capacitance in the unit memory cell. Thus, various methods for increasing a surface area and a height of a bottom electrode of a capacitor have been developed. For example, methods of forming the bottom electrode in a cylindrical or stack shape have been proposed.

### SUMMARY

An embodiment of the inventive concept provides a semiconductor device with improved capacitance, electrical, and reliability characteristics.

An embodiment of the inventive concept provides a method of overcoming a limitation of an etching process, which is performed to fabricate a semiconductor device.

According to an embodiment of the inventive concept, a semiconductor device may include a lower structure, a capacitor on the lower structure, the capacitor including a first bottom electrode, which is extended in a direction perpendicular to a bottom surface of the lower structure, and a second bottom electrode, which is provided on the first bottom electrode, a bottom supporting pattern supporting the first bottom electrode, and a top supporting pattern provided on the bottom supporting pattern to support the first bottom electrode. The first bottom electrode may include a first material, and the second bottom electrode may include a second material. A work function of the second material may be greater than a work function of the first material.

According to an embodiment of the inventive concept, a semiconductor device may include a substrate including active patterns, word lines disposed in the substrate to cross (i.e., traverse) the active patterns, bit lines disposed on the substrate to cross the word lines, a bit line contact disposed on a center portion of each of the active patterns and connected to each of the bit lines, storage node contacts disposed on opposite ends of each of the active patterns, a landing pad on each of the storage node contacts, a capacitor on the landing pad, the capacitor including a first bottom electrode connected to the landing pad and a second bottom electrode disposed on the first bottom electrode, a bottom supporting pattern supporting the first bottom electrode, and a top supporting pattern provided on the bottom supporting pattern to support the first bottom electrode. The second bottom electrode may be in contact with and connected to the first bottom electrode. The second bottom electrode may be provided such that an upper width thereof is larger than a lower width thereof.

According to an embodiment of the inventive concept, a method of fabricating a semiconductor device may include sequentially forming a first mold layer, a bottom supporter layer, a second mold layer, and a top supporter layer on a substrate, performing an etching process on the first mold layer, the bottom supporter layer, the second mold layer, and the top supporter layer to form openings to form a first mold portion, a bottom supporting pattern, a second mold portion, and a top supporting pattern, forming first bottom electrodes to fill the openings, forming additional supporting patterns on the top supporting pattern, and forming second bottom electrodes on the first bottom electrodes to fill a space between the additional supporting patterns.

### BRIEF DESCRIPTION OF THE DRAWINGS

FIG. 1 is a sectional view illustrating an example semiconductor device, according to an embodiment of the inventive concept.

FIGS. 2A to 2H are sectional views illustrating intermediate processes in an example method of fabricating a semiconductor device, according to an embodiment of the inventive concept.

FIG. 3 is a plan view illustrating an example semiconductor device, according to an embodiment of the inventive concept.

FIG. 4 is a sectional view, which is taken along a line A-A′ of FIG. 3, to illustrate an example semiconductor device, according to an embodiment of the inventive concept.

### DETAILED DESCRIPTION

Example embodiments of the inventive concepts will now be described more fully with reference to the accompanying drawings, in which example embodiments are shown. Like reference numerals in the drawings denote like elements, and thus their description will be omitted.

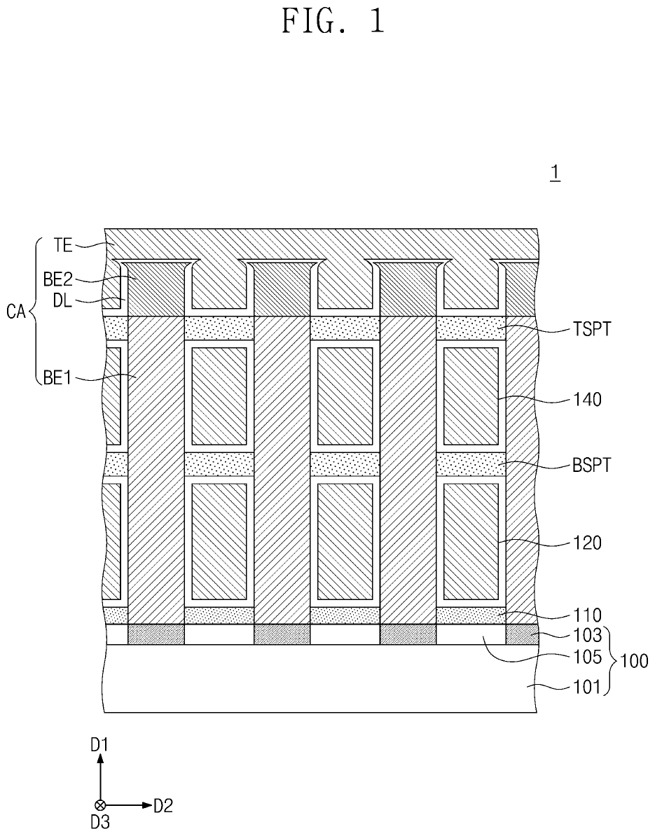

FIG. 1 is a sectional view illustrating an example semiconductor device including a capacitor, according to an embodiment of the inventive concept.

Referring to FIG. 1, a semiconductor device 1 may include a lower structure 100, an etch stop pattern 110, a bottom supporting pattern BSPT, a top supporting pattern TSPT, and a capacitor CA.

The lower structure 100 may include a first substrate 101 and a contact region 103 and an interlayer insulating layer 105 (e.g., an interlayer dielectric (ILD) layer), which are formed on the first substrate 101. In an embodiment, the first substrate 101 may be formed of or include silicon (Si) (e.g., crystalline silicon, polycrystalline silicon, or amorphous silicon). In another embodiment, the first substrate 101 may be formed of or include at least one of semiconductor materials (e.g., germanium (Ge)) or compound semiconductor materials (e.g., silicon germanium (SiGe), silicon carbide (SiC), gallium arsenide (GaAs), indium arsenide (InAs), or indium phosphide (InP)). It is to be understood that embodiments of the inventive concept are not limited to any specific material(s) forming the first substrate 101.

In an embodiment, the contact region 103 may connect a source/drain region (not explicitly shown), which is formed in the first substrate 101, to the capacitor CA. In an embodiment, a plurality of contact regions 103 may be provided. The contact region 103 may be formed of or include at least one of conductive materials (e.g., doped polysilicon, metal, etc.).

The interlayer insulating layer 105 may be interposed between the contact regions 103, which are adjacent to each other. The interlayer insulating layer 105 may be interposed between the first substrate 101 and the etch stop pattern 110 in a first direction D1. The interlayer insulating layer 105 may be interposed between adjacent contact regions 103, laterally separating the adjacent contact regions 103 in a second direction D2 and a third direction D3, the second and third directions D2 and D3, respectively, being in a same plane that is non-parallel with respect to the first direction D1.

The etch stop pattern 110 may be provided on the lower structure 100. The etch stop pattern 110 may be interposed between the interlayer insulating layer 105 of the lower structure 100 and a first bottom electrode BE1 in the first direction D1. The etch stop pattern 110 may be formed of or include at least one of insulating materials (e.g., silicon nitride).

The capacitor CA may be provided on the lower structure 100 and on the etch stop pattern 110. The capacitor CA may include the first bottom electrode BE1, a second bottom electrode BE2, a dielectric layer DL, and a top electrode TE.

The first bottom electrode BE1 may be provided on the contact region 103 of the first substrate 101. In an embodiment, a plurality of first bottom electrodes BE1 may be provided. The first bottom electrodes BE1 may be spaced apart from each other in the second direction D2. Each of the first bottom electrodes BE1 may be in contact with or connected to the contact region 103. Each of the first bottom electrodes BE1 may be shaped like a circular pillar, a hollow cylinder, a cup, or the like. The first bottom electrodes BE1 may be formed of or include at least one of doped polysilicon, doped silicon germanium, metal nitride materials (e.g., titanium nitride), or metallic materials (e.g., titanium, platinum, tungsten, aluminum, and copper); embodiments of the inventive concept are not limited to any particular shape, dimensions and/or materials forming the first bottom electrodes BE1.

The second bottom electrode BE2 may be provided on the first bottom electrode BE1. In an embodiment, a plurality of second bottom electrodes BE2 may be provided. The second bottom electrodes BE2 may be provided on the first bottom electrodes BE1, respectively. A length (i.e., cross-sectional thickness) of the second bottom electrode BE2 in the first direction D1 may be less than a cross-sectional thickness of the first bottom electrode BE1 in the first direction D1. The cross-sectional thickness of the second bottom electrode BE2 in the first direction D1 may be smaller than half of the cross-sectional thickness of the first bottom electrode BE1 in the first direction D1. The second bottom electrode BE2 may be in contact with the first bottom electrode BE1. In the present specification, the first direction D1 may be perpendicular to a top surface of the first substrate 101 (the top surface of the first substrate 101 being parallel to a plane defined by the second and third directions D2 and D3, respectively).

A width, in the second direction D2, of a top surface of the second bottom electrode BE2 may be larger than a width of a bottom surface thereof. A portion of the second bottom electrode BE2 may have a rounded side surface. There may be an interface (not explicitly shown) between the first and second bottom electrodes BE1 and BE2.

In an embodiment, the second bottom electrode BE2 may be formed of or include the same material as that in the first bottom electrode BE1. In other words, the second bottom electrode BE2 may be formed of or include at least one of doped polysilicon, doped silicon germanium, metal nitride materials (e.g., titanium nitride), or metallic materials (e.g., titanium, platinum, tungsten, aluminum, and copper).

Alternatively or in addition, the second bottom electrode BE2 may be formed of or include a material different from the first bottom electrode BE1. A work function of the second bottom electrode BE2 may be greater than that of the first bottom electrode BE1. The work function of the second bottom electrode BE2 may be greater than that of the first bottom electrode BE1 by a range of about 0.1 eV to 1 eV. The second bottom electrode BE2 may be formed of or include a metal nitride material having a work function range from about 4.5 eV to 5.5 eV. For example, the second bottom electrode BE2 may be formed of or include at least one of silicon-doped titanium nitride (TSN), tantalum nitride, molybdenum nitride, niobium nitride, or niobium oxide.

The dielectric layer DL may cover the etch stop pattern 110, the first and second bottom electrodes BE1 and BE2, and the bottom and top supporting patterns BSPT and TSPT. The term “cover” or “covering,” as used herein, is intended to broadly refer to a material, layer or structure formed or otherwise disposed on or over another material, layer or structure, but does not require the material, layer or structure to entirely cover the other material, layer or structure. Thus, for example, a material or layer having openings or holes therein may still be considered to cover another material or layer. The dielectric layer DL may be formed of or include at least one of silicon oxide, silicon nitride, silicon oxynitride, or high-k dielectric materials.

The top electrode TE may be disposed on the dielectric layer DL and may fill a space between the first bottom electrodes BE1 and a space between the second bottom electrodes BE2. The term “fill” (or similarly “filled,” “filling,” or the like), as may be used herein, is intended to broadly refer to either completely filling a defined space (e.g., the space between the first bottom electrodes BE1 and the space between the second bottom electrodes BE2) or partially filling the defined space; that is, the defined space need not be entirely filled but may, for example, be partially filled or have voids or other spaces throughout. The top electrode TE may be formed of or include at least one of doped poly-silicon, doped silicon germanium, metal nitride materials (e.g., titanium nitride), or metallic materials (e.g., tungsten, aluminum, and copper). The first bottom electrode BE1, the second bottom electrode BE2, the dielectric layer DL, and the top electrode TE may constitute the capacitor CA.

The bottom and top supporting patterns BSPT and TSPT may support side surfaces of the first bottom electrode BE1. In detail, the bottom supporting pattern BSPT may support lower side surfaces of the first bottom electrode BE1, and the top supporting pattern TSPT may support upper side surfaces of the first bottom electrode BE1. The bottom and top supporting patterns BSPT and TSPT may be formed of or include at least one of silicon oxide, silicon nitride, silicon oxynitride, or high-k dielectric materials, although embodiments of the inventive concept are not limited thereto.

A top surface of the top supporting pattern TSPT may be located at a level, relative to the lower structure 100, which is equal to or higher than a top surface of the first bottom electrode BE1. The top surface of the top supporting pattern TSPT may be located at a level lower, relative to the lower structure 100, than a top surface of the second bottom electrode BE2.

According to an embodiment of the inventive concept, the capacitor CA of the semiconductor device 1 may include the first bottom electrode BE1 and the second bottom electrode BE2 on the first bottom electrode BE1. The second bottom electrode BE2 may be formed of or include the same material as that in the first bottom electrode BE1. In this case, an electrode may have a large surface area, compared with the case that only the first bottom electrode BE1 is provided, and thus, a capacitance of the capacitor may be increased.

Furthermore, according to an embodiment of the inventive concept, the work function of the second bottom electrode BE2 may be greater than that of the first bottom electrode BE1. In detail, the work function of the second bottom electrode BE2 may be greater than that of the first bottom electrode BE1 by a range of about 0.1 eV to 1 eV. In this case, a difference between the largest energy value of the conduction band of the first bottom electrode BE1 and the smallest energy value of the conduction band of the second bottom electrode BE2 may be increased. This may result in difficulty in transferring electrons from the first bottom electrode BE1 to the second bottom electrode BE2, and thus, a leakage current in the capacitor CA may be reduced. Accordingly, the electrical and reliability characteristics of the semiconductor device 1 may be improved.

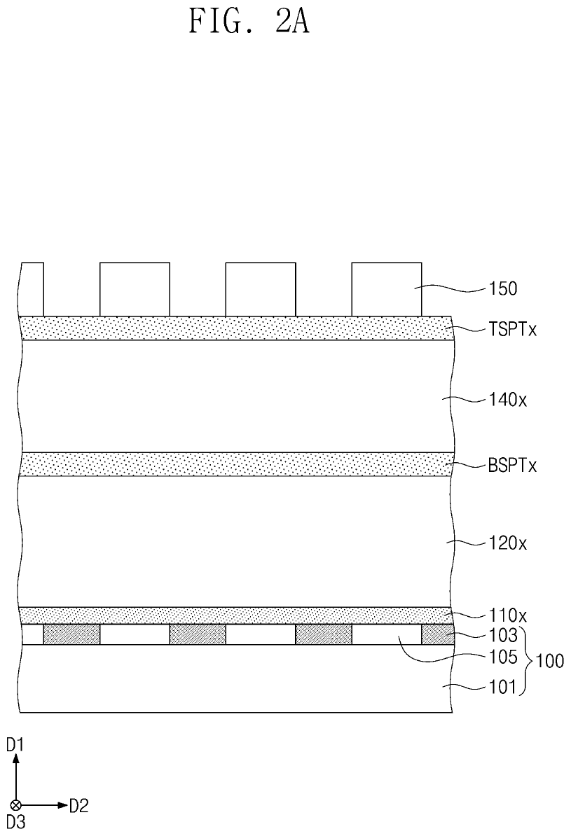

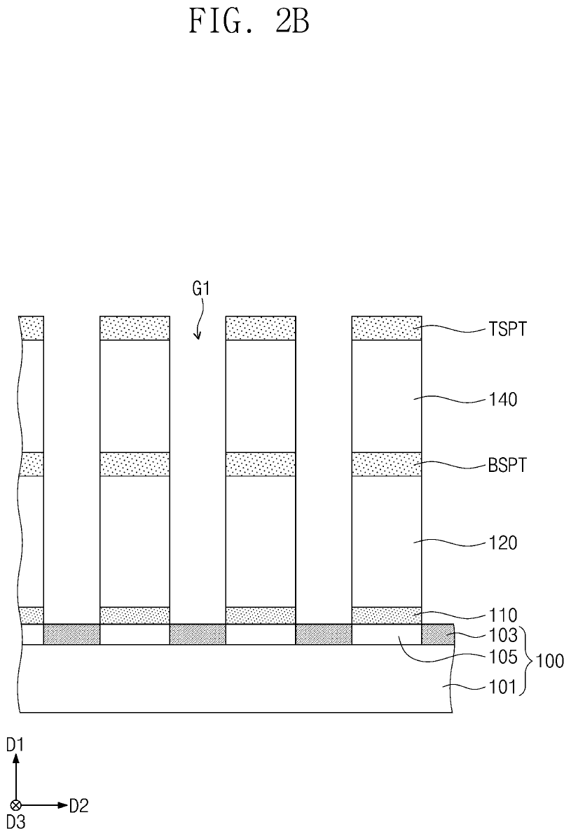

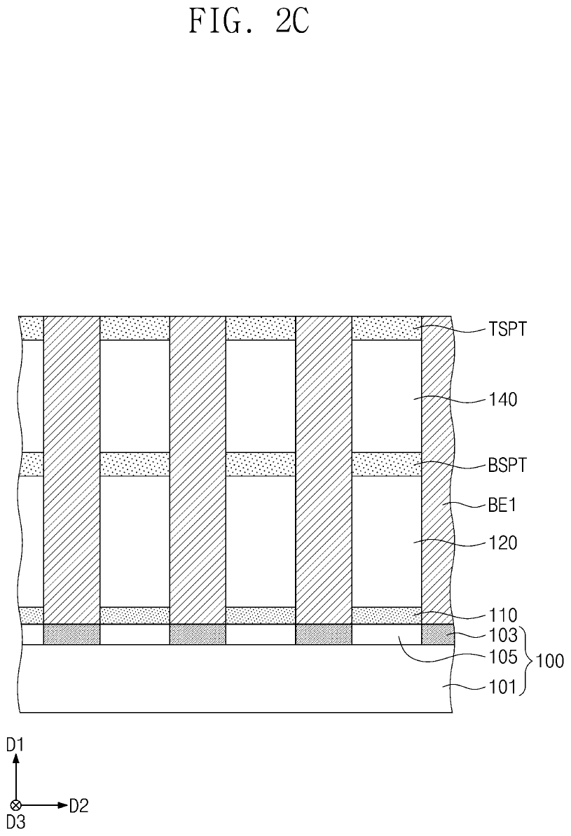

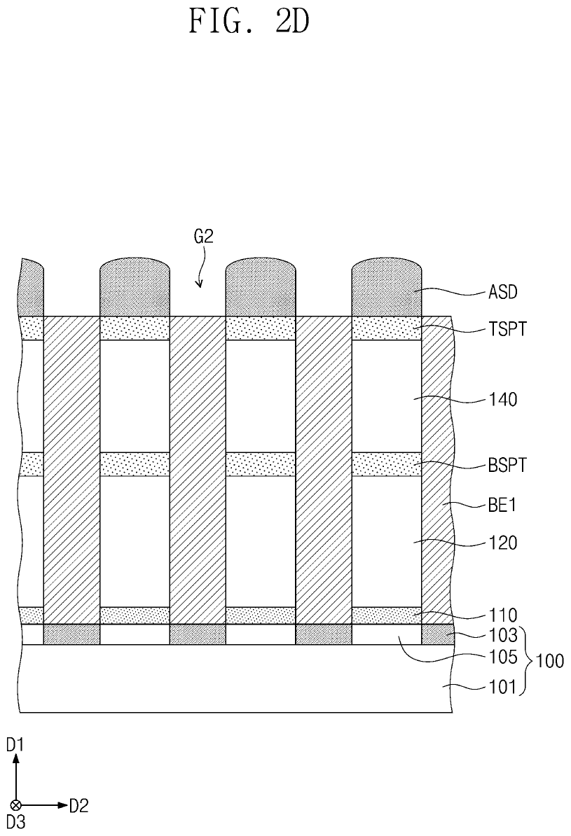

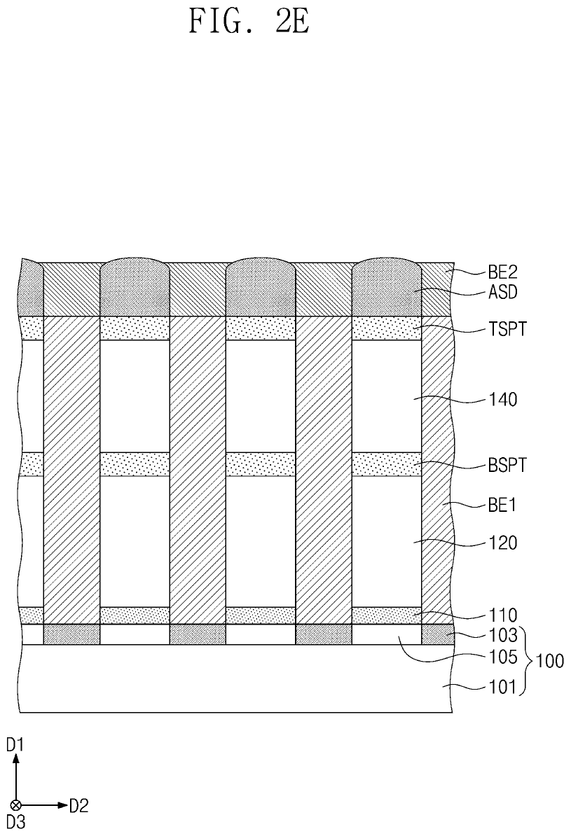

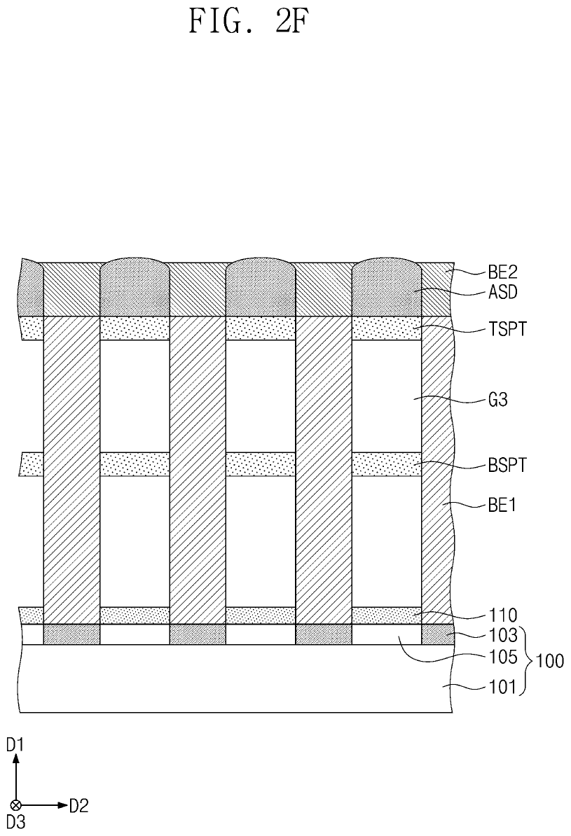

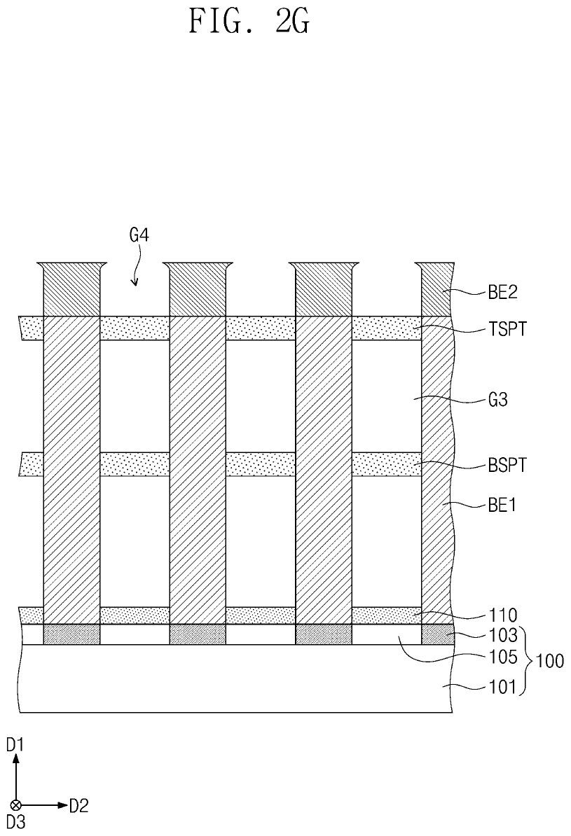

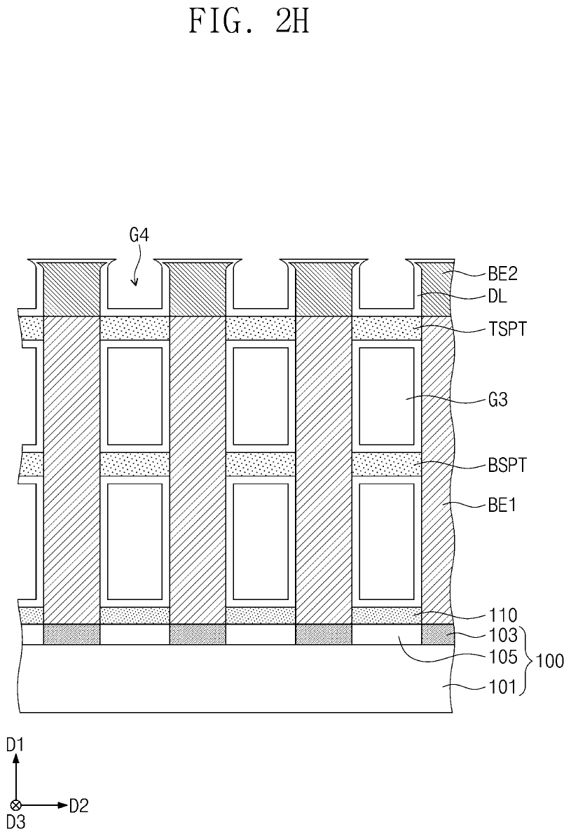

FIGS. 2A to 2H are sectional views illustrating intermediate processing steps in an example method of fabricating a semiconductor device, according to an embodiment of the inventive concept.

Referring to FIG. 2A, the lower structure 100 may include the first substrate 101 and the contact region 103 and the interlayer insulating layer 105, which are formed on the first substrate 101. In an embodiment, the first substrate 101 may be formed of or include silicon (Si) (e.g., crystalline silicon, polycrystalline silicon, or amorphous silicon). In another embodiment, the first substrate 101 may be formed of or include at least one of semiconductor materials (e.g., germanium (Ge)) or compound semiconductor materials (e.g., silicon germanium (SiGe), silicon carbide (SiC), gallium arsenide (GaAs), indium arsenide (InAs), or indium phosphide (InP)). In an embodiment, the contact region 103 may be formed of or include polysilicon.

An etch stop layer 110x, a first mold layer 120x, a bottom supporter layer BSPTx, a second mold layer 140x, and a top supporter layer TSPTx may be sequentially formed on the lower structure 100. The etch stop layer 110x may be used as a layer for detecting an etching end point in a process of etching the first mold layer 120x. Thus, the etch stop layer 110x may be formed of or include a material having an etch selectivity with respect to the first mold layer 120x. The etch stop layer 110x may include, for example, a silicon nitride layer.

In an embodiment, at least one of the first and second mold layers 120x and 140x, respectively, may include a silicon oxide layer. For convenience in description, the present embodiment refers to an example, in which the first and second mold layers 120x and 140x are formed of silicon oxide, but the inventive concept is not limited to this example. In some embodiments, the first and second mold layers 120x and 140x may comprise different materials. The bottom and top supporter layers BSPTx and TSPTx, respectively, may be formed of different materials whose etch rates are different from those of the first and second mold layers 120x and 140x. For example, in the case where, as will be described with reference to FIG. 2F, a lift-off process using, for example, a chemical solution such as one containing HF and NH₄F (“LAL”) or a buffer oxide etchant (“BOE”), is exploited to remove at least one of a first mold portion 120 and a second mold portion 140, the bottom and top supporter layers BSPTx and TSPTx may be formed of or include at least one of materials exhibiting a low etch rate to the LAL solution. If at least one of the first and second mold layers 120x and 140x is formed of silicon oxide, the bottom and top supporter layers BSPTx and TSPTx may be formed of or include at least one of silicon nitride, tantalum oxide, or titanium oxide. However, the materials of the bottom and top supporter layers BSPTx and TSPTx are not limited to those in the above examples.

A mask pattern 150 may be formed on the second mold layer 140x. The mask pattern 150 may be formed to expose a top surface of the top supporter layer TSPTx to the outside at a position corresponding to the contact region 103.

Referring to FIG. 2B, a first opening G1 may be formed by etching the etch stop layer 110x, the first mold layer 120x, the bottom supporter layer BSPTx, the second mold layer 140x, and the top supporter layer TSPTx using the mask pattern 150 as an etch mask. When viewed in a plan view, the first opening G1 may have various shapes (e.g., circular, elliptical, and polygonal shapes). The contact region 103 of the first substrate 101 may be exposed to the outside through the first opening G1. As a result of the etching process, the etch stop pattern 110, the first mold portion 120, the bottom supporting pattern BSPT, the second mold portion 140, and the top supporting pattern TSPT may be formed.

The etching process may be an anisotropic etching process, in which the mask pattern 150 is used as an etch mask. The etch stop pattern 110 may be used as a layer for detecting an end point in the etching process.

A method of etching the first mold layer 120x, the bottom supporter layer BSPTx, the second mold layer 140x, and the top supporter layer TSPTx may depend on the materials used to form the first mold layer 120x, the bottom supporter layer BSPTx, the second mold layer 140x, and the top supporter layer TSPTx. For example, in the case where the first and second mold layers 120x and 140x are formed of silicon oxide, the first and second mold layers 120x and 140x may be etched by an anisotropic dry etching process.

Referring to FIG. 2C, the first bottom electrode BE1, which is connected to the contact region 103, may be formed in the first opening G1. In the present embodiment, the first bottom electrode BE1 is illustrated to have a pillar shape, but the inventive concept is not limited to this shape; for example, the first bottom electrode BE1 may have a cylinder shape.

In an embodiment, at least a subset of the first bottom electrodes BE1 may be formed by depositing a conductive material (not explicitly shown) in the first opening G1 (FIG. 2B) and performing a planarization process (e.g., an etch-back or chemical mechanical polishing (CMP) process) on the conductive material. As a result of the planarization process, the first bottom electrodes BE1 may be electrically disconnected from each other. The top surface of the first bottom electrode BE1 may be located at a level, relative to a top surface of the first substrate 101, which is equal to or lower than the top surface of the top supporting pattern TSPT. In an embodiment, the first bottom electrode BE1 may be formed of or include at least one of doped polysilicon, doped silicon germanium, metal nitride materials (e.g., titanium nitride), or metallic materials (e.g., titanium, platinum, tungsten, aluminum, and copper), although embodiments of the inventive concept are not limited thereto.

Referring to FIG. 2D, an additional supporting pattern ASD may be selectively formed on only the top supporting pattern TSPT. The additional supporting pattern ASD may not exist on the first bottom electrode BE1. In an embodiment, a plurality of additional supporting patterns ASD may be provided. The additional supporting patterns ASD may be spaced apart from each other in the second direction D2. A space between the additional supporting patterns ASD may be referred to as a second opening G2. The top surface of the first bottom electrode BE1 may be exposed to the outside through the second opening G2.

The additional supporting patterns ASD may be formed by a selective deposition method, such as, for example, using an atomic layer deposition (ALD) technology. In an embodiment, a first precursor, which is reacted with the top supporting pattern TSPT but not with the first bottom electrode BE1, may be used in the ALD technology. For example, the first precursor may be injected into a chamber and then may be purged from the chamber, and then, a second precursor may be injected into the chamber. In this case, as a result of the reaction between the first and second precursors, the additional supporting patterns ASD may be formed on only the top supporting pattern TSPT.

Each of at least a subset of the additional supporting patterns ASD may have a shape of a circular pillar or a dome with rounded top. When viewed in a plan view, the additional supporting pattern ASD may have one of various shapes (e.g., circular, elliptical, and polygonal shapes).

A width (in the second direction D2) of a top surface of the additional supporting pattern ASD may be larger than that of a bottom surface thereof. The additional supporting pattern ASD may have a rounded top surface.

The additional supporting pattern ASD may be formed of or include a different material having an etch rate different from those of the first mold portion 120, the second mold portion 140, the bottom supporting pattern BSPT, and the top supporting pattern TSPT. For example, in the case where the first and second mold portions 120 and 140 include silicon oxide and the bottom and top supporting patterns BSPT and TSPT include silicon nitride, the additional supporting pattern ASD may be formed of or include silicon carbon nitride (SiCN). However, the material of the additional supporting pattern ASD is not limited to these example materials.

Referring to FIG. 2E, the second bottom electrodes BE2 may be formed to fill the second openings G2 (FIG. 2D). The formation of the second bottom electrode BE2 may include depositing a conductive material (not explicitly shown) and performing a planarization process (e.g., an etch-back or chemical mechanical polishing (CMP) process) on the conductive material. As a result of the planarization process, the second bottom electrodes BE2 may be electrically disconnected from each other.

Since the second bottom electrode BE2 is formed on the first bottom electrode BE1 by the deposition process, an interface may be present between the second bottom electrode BE2 and the first bottom electrode BE1. A width (in the second direction D2) of the second bottom electrode BE2 may be larger at a top surface thereof than at a bottom surface thereof. A portion of the second bottom electrode BE2 may have a rounded side surface.

The second bottom electrode BE2 may be formed of or include the same material as that in the first bottom electrode BE1. For example, the second bottom electrode BE2 may be formed of or include at least one of doped polysilicon, doped silicon germanium, metal nitride materials (e.g., titanium nitride), or metallic materials (e.g., titanium, platinum, tungsten, aluminum, and copper).

In other embodiments, the second bottom electrode BE2 may be formed of or include a material different from the first bottom electrode BE1. The work function of the second bottom electrode BE2 may be greater than the work function of the first bottom electrode BE1. The work function of the second bottom electrode BE2 may be greater than that of the first bottom electrode BE1 by a range of about 0.1 eV to 1 eV. The second bottom electrode BE2 may be formed of or include a metal nitride material having a work function range from about 4.5 eV to 5.5 eV. For example, the second bottom electrode BE2 may be formed of or include at least one of silicon-doped titanium nitride (TSN), tantalum nitride, molybdenum nitride, niobium nitride, or niobium oxide.

According to an embodiment of the inventive concept, by using the first precursor, which is reacted with the top supporting pattern TSPT but not with the first bottom electrode BE1, the additional supporting pattern ASD may be formed on only the top supporting pattern TSPT. That is, since the additional supporting pattern ASD is selectively formed on only the top supporting pattern TSPT, even a material, which is not easily patterned by a three-dimensional patterning method, may be easily patterned. Accordingly, it may be possible to easily form the second bottom electrode BE2, which includes a material with a greater work function than that of the first bottom electrode BE1, and consequently to facilitate the process of fabricating the semiconductor device 1.

According to an embodiment of the inventive concept, the bottom electrode of the capacitor CA may be composed of the first and second bottom electrodes BE1 and BE2. In this case, an area of the bottom electrode of the capacitor CA may be increased, compared with the capacitor composed of only the first bottom electrode BE1. Thus, a capacitance of the capacitor CA may be increased.

In addition, since the second bottom electrode BE2 is additionally formed on the first bottom electrode BE1 by forming the additional supporting pattern ASD, it may be possible to overcome technical limitations in a process of increasing a length of the first bottom electrode BE1.

Referring to FIG. 2F, the first and second mold portions 120 and 140 may be removed to form a third opening G3. The first and second mold portions 120 and 140 may be removed by a lift-off process using hydrofluoric acid or LAL solution. The removal of the first and second mold portions 120 and 140 may be performed to sequentially remove the second mold portion 140 and the first mold portion 120 or to simultaneously remove the first and second mold portions 120 and 140. In an embodiment, the first and second mold portions 120 and 140 may be removed through a wet etching process.

Here, since the bottom supporting pattern BSPT, the top supporting pattern TSPT, and the additional supporting pattern ASD have an etch selectivity with respect to the first and second mold portions 120 and 140, they may not be removed by the lift-off process. The first bottom electrode BE1, the bottom supporting pattern BSPT, and the top supporting pattern TSPT may be exposed to the outside through the third opening G3.

Referring to FIG. 2G, the additional supporting pattern ASD may be removed. The removal of the additional supporting pattern ASD may be performed using an isotropic etching process. A space, which is formed by removing the additional supporting pattern ASD, may form a fourth opening G4. The top surface of the top supporting pattern TSPT may be exposed to the outside through the fourth opening G4.

Referring to FIG. 2H, the dielectric layer DL may be formed to cover (e.g., conformally coat) portions of the etch stop pattern 110, the bottom supporting pattern BSPT, the top supporting pattern TSPT, the first bottom electrode BE1, and the second bottom electrode BE2 that are exposed through the third and fourth openings G3 and G4. The dielectric layer DL may be formed of or include at least one of silicon oxide or high-k dielectric materials.

Referring back to FIG. 1, the top electrode TE may be formed on the dielectric layer DL. The top electrode TE may be formed to fill the third opening G3 and the fourth opening G4. The top electrode TE may be spaced apart (and electrically isolated) from the first and second bottom electrodes BE1 and BE2 with the dielectric layer DL interposed therebetween. The first bottom electrode BE1, the second bottom electrode BE2, the dielectric layer DL, and the top electrode TE may constitute the capacitor CA. As a result, the semiconductor device 1 may be formed.

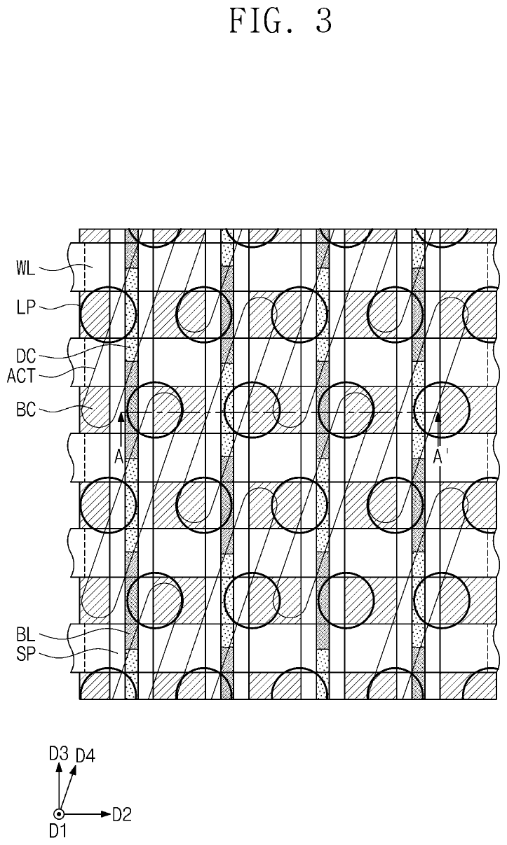

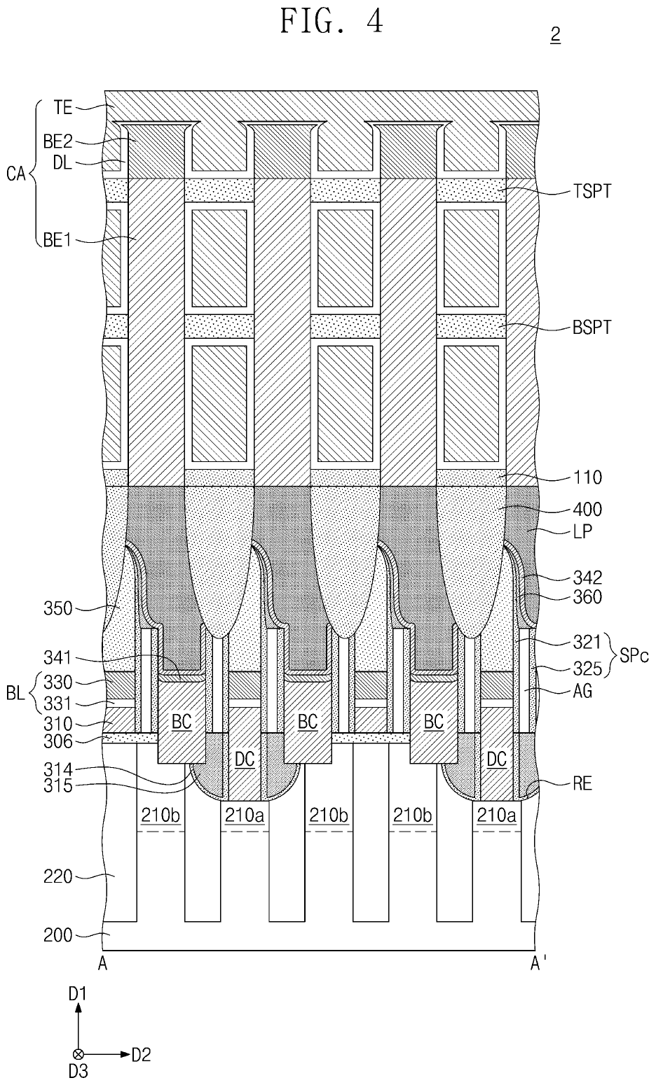

FIG. 3 is a plan view illustrating an example semiconductor device, according to an embodiment of the inventive concept. FIG. 4 is a sectional view, which is taken along a line A-A′ of FIG. 3 to illustrate an example semiconductor device according to an embodiment of the inventive concept. In the following description of FIGS. 3 and 4, an element described with reference to FIG. 1 may be identified by the same reference number without repeating an overlapping description thereof.

Referring to FIGS. 3 and 4, a semiconductor device 2 may include a second substrate 200. Active patterns ACT may be disposed on the second substrate 200. When viewed in a plan view (FIG. 3), the active patterns ACT may be spaced apart from each other in the second direction D2 and the third direction D3. The active patterns ACT may be bar-shaped patterns, which are extended in a fourth direction D4 that is parallel to a bottom surface of the second substrate 200 (i.e., a plane extending in the second and third directions D2 and D3) and is non-parallel to the second and third directions D2 and D3. The second direction D2 may be non-parallel to the first direction D1 and may be parallel to the top surface of the first substrate 101. The third direction D3 may be non-parallel to the first and second directions D1 and D2 and may be parallel to the top surface of the first substrate 101.

Device isolation layers 220 may be disposed between the active patterns ACT to electrically isolate the active patterns ACT from one another. The device isolation layers 220 may be disposed in the second substrate 200 to define the active patterns ACT.

Word lines WL may be disposed to cross (i.e., traverse) the active patterns ACT and the device isolation layers 220. The word lines WL may be disposed in grooves, which are formed in the active patterns ACT and the device isolation layers 220. The word lines WL may be extended in the second direction D2 and may be spaced apart from each other the third direction D3. The word lines WL may be buried in the second substrate 200.

First and second impurity regions 210a and 210b may be provided in the active patterns ACT. Each of the first impurity regions 210a may be provided between a pair of the word lines WL, which are disposed to cross each of the active patterns ACT. The second impurity regions 210b may be provided in opposite edge regions of each of the active patterns ACT. The first impurity regions 210a may include impurities, which are of the same conductivity type (e.g., n-type) as the second impurity regions 210b.

A buffer pattern 306 may be disposed on the second substrate 200 to cover the active patterns ACT, the device isolation layers 220, and the word lines WL. In an embodiment, the buffer pattern 306 may be formed of or include at least one of silicon oxide, silicon nitride, and/or silicon oxynitride.

Bit lines BL may be disposed on the buffer pattern 306. The bit lines BL may be extended in the third direction D3 and may be spaced apart from each other in the second direction D2. Each of the bit lines BL may include a barrier pattern 331 and a metal-containing pattern 330 sequentially stacked. The barrier pattern 331 may be formed of or include at least one of metal nitride materials (e.g., TiN, TSN, and TaN). In an embodiment, the metal-containing pattern 330 may be formed of or include at least one of metallic materials (e.g., tungsten, titanium, and tantalum).

Polysilicon patterns 310 may be interposed between the bit lines BL and the buffer pattern 306. The polysilicon patterns 310 may be formed of or include doped or undoped polysilicon. Although not explicitly shown, a first ohmic pattern may be provided between the barrier pattern 331 and the corresponding polysilicon pattern 310. In an embodiment, the first ohmic pattern may be formed of or include, for example, at least one of metal silicide materials.

Bit line contacts DC may be respectively interposed between the bit lines BL and the first impurity regions 210a. The bit lines BL may be electrically connected to the first impurity regions 210a by the bit line contacts DC. The bit line contacts DC may be formed of or include, for example, doped or undoped polysilicon.

The bit line contacts DC may be disposed in a recess region RE. The recess region RE may be formed in upper portions of the first impurity regions 210a and upper portions of the device isolation layers 220 adjacent thereto. A first gapfill insulating pattern 314 and a second gapfill insulating pattern 315 may fill a remaining portion of the recess region RE.

A capping pattern 350 may be provided on each of the bit lines BL and may be extended in the second direction D2. The capping pattern 350 may be formed of or include, for example, silicon nitride.

A side surface of each of the polysilicon patterns 310, an upper side surface of each of the bit line contacts DC, a side surface of each of the bit lines BL, and a side surface of the capping pattern 350 may be covered with a bit line spacer SPc. The bit line spacer SPc may be extended along each of the bit lines BL and in the first direction D1.

The bit line spacer SPc may include a first sub-spacer 321 and a second sub-spacer 325, which are spaced apart from each other. In an embodiment, the first sub-spacer 321 and the second sub-spacer 325 may be spaced apart from each other by an air gap AG. The first sub-spacer 321 may be in contact with the side surface of each of the bit lines BL and may be extended in the second direction D2 to cover the side surface of the capping pattern 350. The second sub-spacer 325 may be provided to extend along a side surface of the first sub-spacer 321. Each of the first and second sub-spacers 321 and 325 may be formed of or include, for example, silicon nitride.

An upper spacer 360 may cover the side surface of the first sub-spacer 321 and may be extended to a top surface of the second sub-spacer 325. The upper spacer 360 may further cover the air gap AG.

Storage node contacts BC may be interposed between adjacent ones of the bit lines BL. The storage node contacts BC may be spaced apart from each other in the second and third directions D2 and D3, respectively. The storage node contacts BC may be formed of or include, for example, doped or undoped polysilicon.

A second cell ohmic pattern 341 may be disposed on each of the storage node contacts BC. In an embodiment, the second cell ohmic pattern 341 may be formed of or include, for example, at least one of metal silicide materials.

A cell diffusion prevention pattern 342 may conformally cover the second cell ohmic pattern 341, the bit line spacer SPc, and the capping pattern 350. The cell diffusion prevention pattern 342 may be formed of or include at least one of metal nitride materials (e.g., TIN, TSN, and TaN). The second cell ohmic pattern 341 may be interposed between the cell diffusion prevention pattern 342 and each of the storage node contacts BC.

Landing pads LP may be disposed on the storage node contacts BC, respectively. The landing pads LP may be spaced apart from each other in the second and third directions D2 and D3. The landing pads LP may be formed of or include, for example, at least one of metallic materials (e.g., tungsten).

A filler pattern 400 may enclose each of the landing pads LP. The filler pattern 400 may be interposed between adjacent ones of the landing pads LP. The filler pattern 400 may be an element corresponding to the interlayer insulating layer 105 of FIG. 1.

The etch stop pattern 110, the bottom supporting pattern BSPT, the top supporting pattern TSPT, and the capacitor CA may be disposed on the landing pads LP and the filler pattern 400. The etch stop pattern 110, the bottom supporting pattern BSPT, the top supporting pattern TSPT, and the capacitor CA may be the same features as the etch stop pattern 110, the bottom supporting pattern BSPT, the top supporting pattern TSPT, and the capacitor CA of FIG. 1. The capacitor CA may include the same elements as those in the capacitor CA of FIG. 1.

The etch stop pattern 110 may be provided on the filler pattern 400. Here, the filler pattern 400 may be an element corresponding to the interlayer insulating layer 105 of FIG. 1. The first bottom electrode BE1 may be in contact with and connected to the landing pad LP. Here, the landing pads LP may be an element corresponding to the contact region 103 of FIG. 1.

According to an embodiment of the inventive concept, a capacitor of a semiconductor device may include a first bottom electrode and a second bottom electrode on the first bottom electrode. A work function of the second bottom electrode may be greater than a work function of the first bottom electrode. In detail, the work function of the second bottom electrode may be greater than that of the first bottom electrode by a range of about 0.1 eV to 1 eV. In this case, a difference between the largest energy value of the conduction band of the first bottom electrode and the smallest energy value of the conduction band of the second bottom electrode may be increased, and thus, there may be a difficulty in electron transfer from the first bottom electrode to the second bottom electrode. Accordingly, it may be possible to reduce a leakage current in the capacitor, and thus, electrical and reliability characteristics of the semiconductor device may be improved.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Spatially descriptive terms such as “above,” “over,” “below,” “upper” and “lower” may be used herein to indicate a position of elements, structures or features relative to one another as illustrated in the figures, rather than absolute positioning. Thus, the semiconductor device may be otherwise oriented (e.g., rotated 90 degrees or at other orientations), and the spatially relative descriptions used herein may be interpreted accordingly.

It will also be understood that when an element such as a layer, region or substrate is referred to as being “atop,” “above,” “on” or “over” another element, it is broadly intended that the element be in direct contact with the other element or intervening elements can also be present. In contrast, when an element is referred to as being “directly on” or “directly over” another element, it is intended that there are no intervening elements present. Likewise, it should be appreciated that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a lower structure;
a capacitor on the lower structure, the capacitor including a first bottom electrode, which is extended in a direction perpendicular to a bottom surface of the lower structure, and a second bottom electrode on the first bottom electrode;
a bottom supporting pattern configured to support the first bottom electrode; and
a top supporting pattern on the bottom supporting pattern configured to support the first bottom electrode,
wherein the first bottom electrode includes a first material,
the second bottom electrode includes a second material, and
a work function of the second material is greater than a work function of the first material.

2. The semiconductor device of claim 1, wherein a top surface of the first bottom electrode is at a level, relative to the bottom surface of the lower structure, which is equal to or lower than a top surface of the top supporting pattern, and
a top surface of the second bottom electrode is located at a level, relative to the bottom surface of the lower structure, which is higher than the top surface of the top supporting pattern.

3. The semiconductor device of claim 1, wherein the second bottom electrode has a width, in a direction parallel to the bottom surface of the lower structure, that is larger at a top surface thereof than at a bottom surface thereof.

4. The semiconductor device of claim 1, wherein the work function of the second material ranges from 4.5 eV to 5.5 eV.

5. The semiconductor device of claim 1, wherein the second material includes at least one of silicon-doped titanium nitride, tantalum nitride, molybdenum nitride, niobium nitride, and niobium oxide.

6. The semiconductor device of claim 5, wherein the first material includes at least one of doped polysilicon, doped silicon germanium, titanium nitride, titanium, platinum, tungsten, aluminum, and copper.

7. The semiconductor device of claim 1, wherein a cross-sectional thickness of the second bottom electrode is smaller than half of a cross-sectional thickness of the first bottom electrode.

8. The semiconductor device of claim 1, wherein the capacitor further includes a dielectric layer, which is on at least a portion of the first bottom electrode and at least a portion of the second bottom electrode.

9. The semiconductor device of claim 8, wherein the capacitor further includes a top electrode on a surface of the dielectric layer, and
the top electrode is spaced apart from the first and second bottom electrodes with the dielectric layer interposed therebetween.

10. The semiconductor device of claim 1, wherein the bottom supporting pattern includes a same material as the top supporting pattern.

11. A semiconductor device, comprising:
a substrate including active patterns;
word lines disposed on the substrate to traverse the active patterns;
bit lines disposed on the substrate to traverse the word lines;
a bit line contact disposed on a center portion of one of the active patterns and connected to one of the bit lines;
storage node contacts disposed on opposite ends of each of the active patterns;
a landing pad on one of the storage node contacts;
a capacitor on the landing pad, the capacitor including a first bottom electrode connected to the landing pad and a second bottom electrode disposed on the first bottom electrode;
a bottom supporting pattern configured to support the first bottom electrode; and
a top supporting pattern on the bottom supporting pattern and configured to support the first bottom electrode,
wherein the second bottom electrode is connected to the first bottom electrode, and
the second bottom electrode is configured such that an upper width thereof, in a direction parallel to a top surface of the substrate, is larger than a lower width thereof.

12. The semiconductor device of claim 11, wherein a portion of the second bottom electrode has a rounded side surface.

13. The semiconductor device of claim 11, wherein the first bottom electrode comprises a first material and the second bottom electrode comprises a second material, and wherein a work function of the second material is greater than a work function of the first material by a range of 0.1 eV to 1 eV.

14. The semiconductor device of claim 11, wherein an interface is present between the second bottom electrode and the first bottom electrode.

15. A method of fabricating a semiconductor device, comprising:
sequentially forming a first mold layer, a bottom supporter layer, a second mold layer, and a top supporter layer on a substrate;
performing an etching process on the first mold layer, the bottom supporter layer, the second mold layer, and the top supporter layer to form openings, thereby forming a first mold portion, a bottom supporting pattern, a second mold portion, and a top supporting pattern;
forming first bottom electrodes to at least partially fill the openings;
forming additional supporting patterns on the top supporting pattern; and
forming second bottom electrodes on the first bottom electrodes to at least partially fill a space between the additional supporting patterns.

16. The method of claim 15, wherein the additional supporting patterns are not formed on the first bottom electrodes or the second bottom electrodes.

17. The method of claim 15, wherein the additional supporting patterns include a material different from the first mold portion, the bottom supporting pattern, the second mold portion, and the top supporting pattern.

18. The method of claim 15, further comprising removing the additional supporting patterns, after the forming of the second bottom electrodes.

19. The method of claim 15, wherein forming the additional supporting patterns includes performing an atomic layer deposition (ALD) method using a precursor, which is reacted with the top supporting pattern but not with the first bottom electrodes.

20. The method of claim 15, wherein forming the second bottom electrodes includes:
forming a conductive material to at least partially fill a space between the additional supporting patterns; and
performing a planarization process on the conductive material to expose a top surface of the additional supporting patterns.
